(19) United States
(12) Patent Application Publication
(10) Pub. No.: US 2018/0114699 A1
(43) Pub. Date: Apr. 26, 2018

(54) Method for Self-Aligned Cutting of Single Fins

(71) Applicant: Tokyo Electron Limited, Tokyo (JP)

(72) Inventor: Nihar Mohanty, Clifton Park, NY (US)

(21) Appl. No.: 15/788,269

(22) Filed: Oct. 19, 2017

Related U.S. Application Data
(60) Provisional application No. 62/410,808, filed on Oct. 20, 2016.

(51) Int. Cl. H01L 21/308; H01L 21/3065; H01L 29/66

(52) U.S. Cl. CPC H01L 21/3088; H01L 21/3065; H01L 29/66795; H01L 21/3085; H01L 21/3086; H01L 21/3081

(57) ABSTRACT

Techniques herein use a self-alignment based process that enables single fin cutting (cutting a single fin among other fins) with overlay requirements relaxed by as much as three times. Embodiments can achieve this benefit by forming fins that use multiple different materials. For example, an array of fins can include parallel fins that alternate in type of material that comprises each fin. Different materials are selected that have different etch resistivities. With such a configuration, an etch mask that uncovers more than one fin (due to overlay error and/or lithographic resolution constraints) can nevertheless cut a desired fin using a combination of an etch mask and differing material resistivities.

### CROSS REFERENCE TO RELATED APPLICATIONS

The present application claims the benefit of U.S. Provisional Patent Application No. 62/410,808, filed on Oct. 20, 2016, entitled “Method for Self-Aligned Cutting of Single Fins,” which is incorporated herein by reference in its entirety.

### BACKGROUND OF THE INVENTION

This disclosure relates to semiconductor fabrication including processing of substrates such as semiconductor wafers.

### SUMMARY

Semiconductor devices are continually being scaled down to fit more devices per unit area of a substrate. To maintain such areal scaling, single finFET devices are being adopted at N10 (node 10) and beyond. This adoption is a significant departure from previous technology nodes in which two to three fins comprised a single device. As can be appreciated, designing a single fin for each device makes accurate fin cut processes more important because there is no redundancy. Working at sub-30 nm pitch dimensions, cutting a single fin—while leaving the adjacent fin intact—is a significant overlay challenge. Irrespective of a given lithographic exposure technique used for a fin cut, any overlay variation can result in the wrong fin being cut or the correct fin receiving only a partial fin cut. Such overlay error will resulting in defects, yield loss, and even device failure.

Techniques herein use a self-alignment based process that enables single fin cutting (cutting a single fin among other fins) with overlay requirements relaxed by as much as 300%. Techniques include a method of patterning a substrate. A first set of fin structures is formed on a substrate. The first set of fin structures is formed as a first array of parallel lines. A spacing of given adjacent fin structures of the first set of fin structures is sufficient to permit additional fin structures to be interposed among fin structures of the first set of fin structures. Such a result can include an array of alternating fin structures with space between a given fin structure of the first set of fin structures and a given adjacent fin structure of additional fin structures. The substrate is planarized by depositing a first fill material that fills spaces between fins of the first set of fin structures.

A second set of fin structures is formed on the substrate. The second set of fin structures is formed as a second array of parallel lines. The second set of fin structures is positioned so that fin structures of the second set of fin structures are elevationally interposed with fins of the first set of fin structures. A first etch process is executed that transfers a pattern comprising the second set of fin structures into the first fill material without removing the first set of fin structures. The first etch process results in a third set of fin structures. Fin structures of the third set of fin structures alternate with fin structures of the first set of fin structures. The third set of fin structures is in plane with the first set of fin structures. The first set of fin structures have a different etch resistivity as compared to the third set of fin structures. One or more etch masks can then be used to cut (remove by etching) a given fin structure using an etch chemistry that etches a material of a given fin without etching adjacent fins, which adjacent fins are comprised of a different material.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete appreciation of various embodiments of the invention and many of the attendant advantages thereof will become readily apparent with reference to the following detailed description considered in conjunction with the accompanying drawings. The drawings are not necessarily to scale, with emphasis instead being placed upon illustrating the features, principles and concepts.

FIGS. 1-14 are cross-sectional schematic side views of an example substrate segment showing a process flow according to embodiments disclosed herein.

FIGS. 15-27 are cross-sectional schematic side views of an example substrate segment showing an alternative process flow according to embodiments disclosed herein.

### DETAILED DESCRIPTION

Techniques herein use a self-alignment based process that enables single fin cutting (cutting a single fin among other fins) with overlay requirements relaxed by as much as 300%. Embodiments can achieve this benefit by forming fins that use multiple different materials. For example, an array of fins can include parallel fins that alternate in type of material that comprises each fin. Different materials are selected that have different etch resistivities. With such a configuration, an etch mask that uncovers more than one fin (due to overlay error and/or lithographic resolution constraints) can nevertheless cut a desired fin using a combination of the etch mask and differing material resistivities. In other words, an array of fins is formed having odd and even fins and spaces between adjacent fins. With odd fins of one material, and even fins of another material, either the odd or even fins can be selectively etched without substantially etching the other fins even when the other fins are uncovered and exposed to etchants.

In conventional techniques, fins are formed of a single material. There is some distance or space between each fin. When an etch mask is formed to cut a given fin, the etch mask can have an opening that uncovers an adjacent fin or part of an adjacent fin. With an adjacent fin uncovered, both the target fin and the adjacent fin are etched being of a same material. With techniques herein, however, a given fin/line can be comprised of a first material, such as oxide, while adjacent lines are comprised of a second material, such as nitride. Etch chemistries are conventionally available that can etch oxide without etching nitride. There are many other material options and etch chemistries to selectively etch one material without etching other materials.

A more detailed description of an example embodiment will now be described. By decomposing a final quadruple pitch pattern into odd and even spacers and forming them through two grid lithographic passes, an alternating structure is generated that is comprised of different materials. As a lithographic grid shift has very low overlay error, this technique does not introduce additional overlay errors. Furthermore, unlike conventional techniques, techniques herein use spacers to form fins. Using spacers for fins is beneficial for fin CD control at advanced nodes.

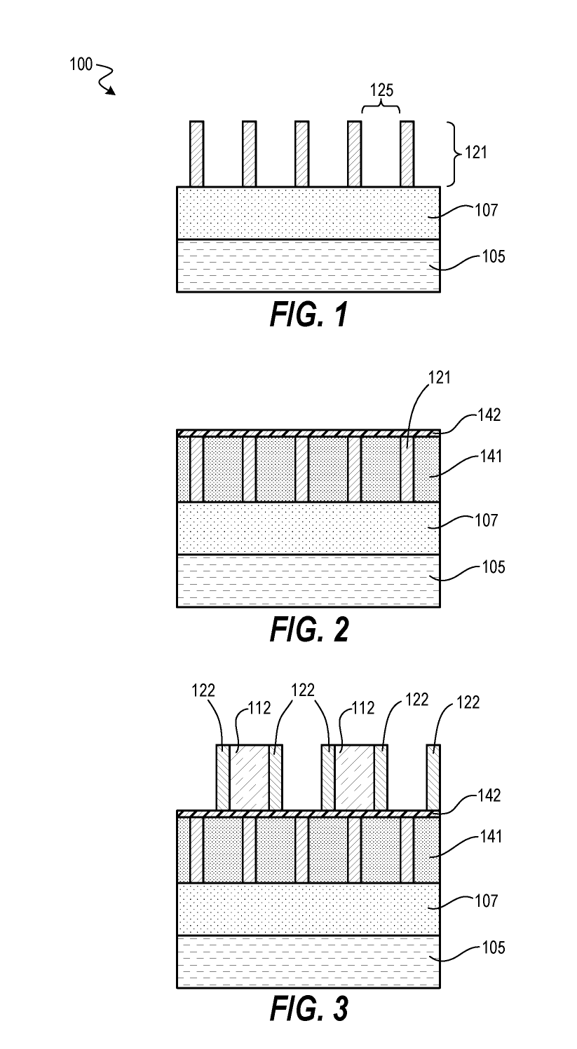

A substrate stack can be prepared having several layers depending on a given microfabrication flow. Mandrels can be patterned in photoresist and developed and transferred into an underlying layer, such as a carbon layer. Sidewall spacers can then be formed on the mandrels. Sidewall spacer formation is known. Typically a conformal film is deposited on a substrate with mandrels (which could be lines). Then a spacer etch process is executed that is a partial etch of the conformal film material. The partial etch removes conformal film material from tops of the mandrels and from the floor material. Basically, the conformal film material is removed from horizontal surfaces. The remaining conformal material is on sidewalls of the mandrels. The mandrels can then be removed by an etch process that etches mandrel material without etching the conformal film material. What is left on the substrate is a set of sidewall spacers. FIG. 1 illustrates this result.

Thus, a first set of fin structures 121 is formed on the substrate 100. The first set of fin structures 121 is formed as a first array of parallel lines. A spacing 125 of given adjacent fin structures of the first set of fin structures is sufficient to permit additional fin structures to be interposed among fin structures of the first set of fin structures 121. Such interposition can result in an array of alternating fin structures with space between a given fin structure of the first set of fin structures and a given adjacent fin structure of additional fin structures. In one embodiment, a pitch of the first set of fin structures can be twice a design pitch of fins for a given region of the substrate. In other words, odd fin structures are formed with enough room between each other to form an even fin structure between pairs of adjacent odd fin structures. The first set of fin structures can be positioned on target layer 107. The substrate can include underlying layer 105 and more underlying layers, interfacial films, et cetera.

Substrate 100 is planarized by depositing a first fill material 141 that fills spaces between fins of the first set of fin structures 121. An optional cap layer 142 can be used to help with planarization. FIG. 2 illustrates an example result.

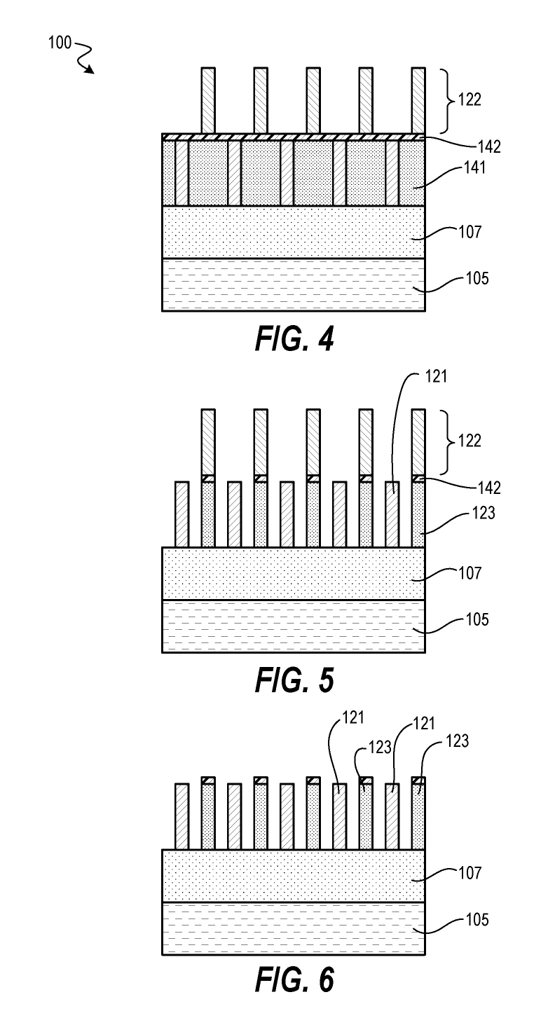

Referring now to FIG. 3, a second set of fin structures 122 is formed on substrate 100. FIG. 3 shows mandrels 112 used to guide formation of the second set of fin structures 122. Mandrels 112 can be formed with a conventional lithographic patterning process. Thus, prior to this step, other planarization layers, interfacial films, anti-reflective coatings and photoresist layers can be deposited and removed. The second set of fin structures 122 is formed as a second array of parallel lines. The second set of fin structures 122 is positioned so that fin structures of the second set of fin structures 122 are elevationally interposed with fins of the first set of fin structures. By observation of FIG. 4, it can be seen that fins of the second set of fin structures 122 are positioned above spaces between fins of the first set of fin structures 121. Viewing from a z-direction or top view, the two sets of fin structures alternate with each other even though they are on different layers or elevations.

A first etch process is executed that transfers a pattern comprising the second set of fin structures 122 into the first fill material 141 without removing the first set of fin structures 121. The first etch process results in a third set of fin structures 123. An example result is illustrated in FIG. 5. The second set of fin structures 122 can be removed, as illustrated in FIG. 6. Fin structures (individual lines) of the third set of fin structures 123 alternate with fin structures (individual lines) of the first set of fin structures 121. The third set of fin structures 123 is in plane with the first set of fin structures 121. The first set of fin structures 121 has a different etch resistivity as compared to the third set of fin structures 123.

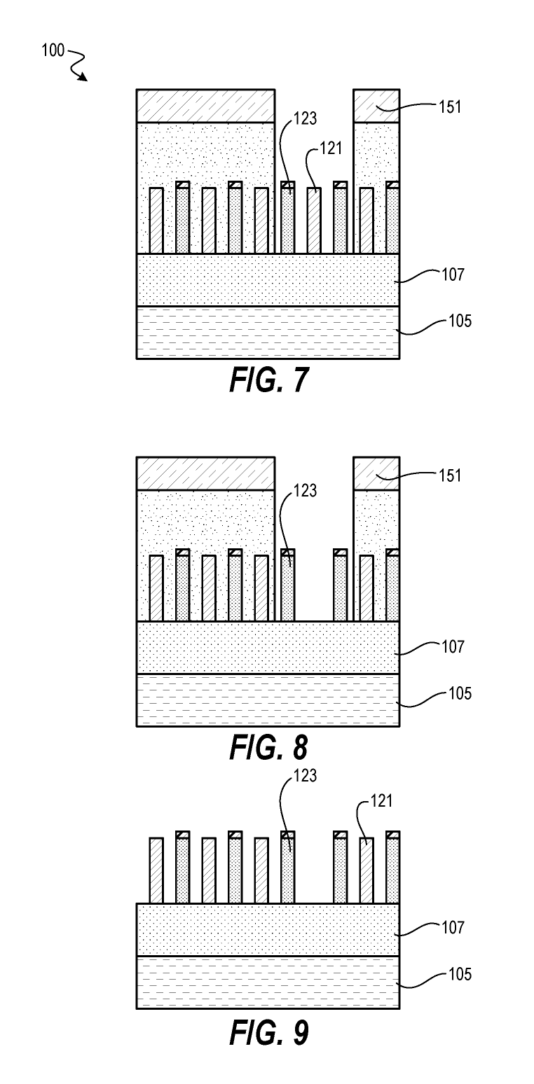

A first etch mask 151 is formed on the substrate that uncovers portions of the first set of fin structures 121 and the third set of fin structures 123. FIG. 7 illustrates an example side view. A second etch process is executed using the first etch mask 151. The second etch process etches uncovered portions of the first set of fin structures 121 at a greater rate than etching of uncovered portions of the third set of fin structures 123 until uncovered portions of the first set of fin structures are removed from the substrate while uncovered portions of the third set of fin structures remain on the substrate. Note that FIG. 8 illustrates uncovered portions of the first set of fin structures having been removed, while adjacent uncovered fins remain. Preferably, etch chemistry is selected that has little to no etching of adjacent material, but having an etch rate of four to one or greater can nevertheless be sufficient. The first etch mask 151 can then be removed from substrate 100, as illustrated in FIG. 9.

In some embodiments, a third etch process can be executed using the first etch mask 151. The third etch process etches uncovered portions of the third fin structures until uncovered portions of the third fin structures are removed from the substrate. This can be executed by changing a particular etch chemistry.

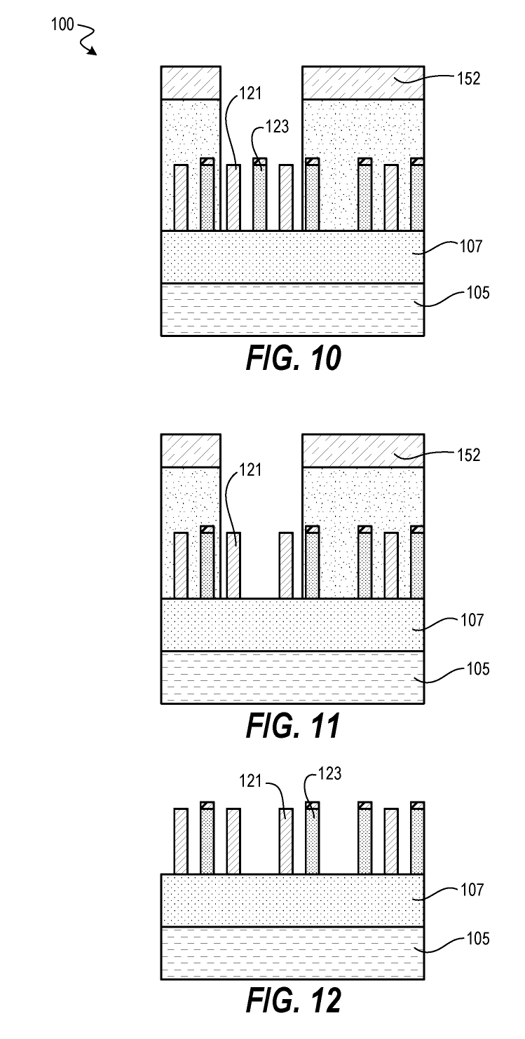

A second etch mask 152 is formed on the substrate that uncovers portions of the first set of fin structures 121 and portions of the third set of fin structures 123. An example result is illustrated in FIG. 10. A fourth etch process is executed using the second etch mask 152. The fourth etch process etches uncovered portions of the third set of fin structures 123 at a greater rate than etching of uncovered portions of the first set of fin structures 121 until uncovered portions of the third set of fin structures 123 are removed from the substrate while uncovered portions of the first set of fin structures remain on the substrate. FIG. 11 illustrates an example result with an uncovered fin from the third set of fin structures having been removed. Second etch mask 152 and accompanying planarization layers/materials can then be removed (FIG. 12).

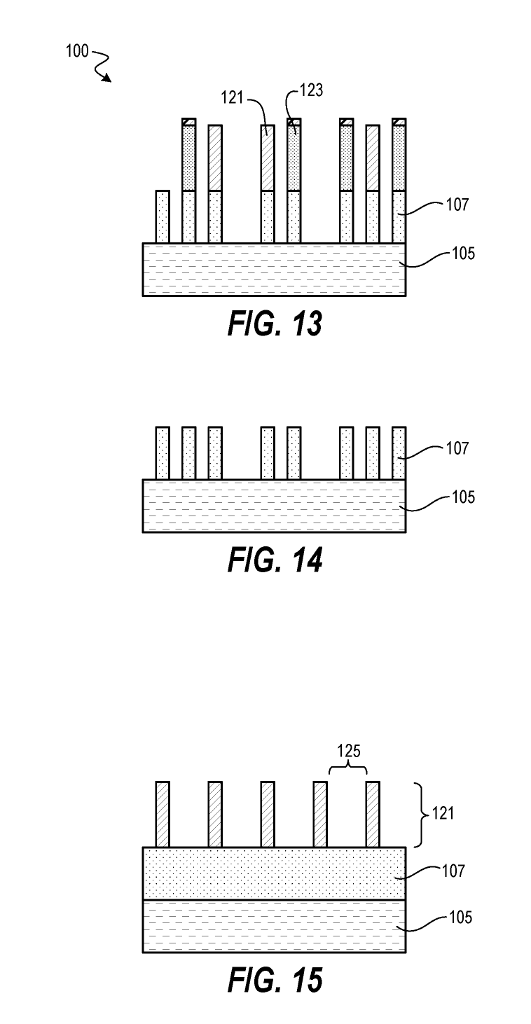

A fifth etch process can then be executed that transfers a combined pattern into an underlying layer, such as target layer 107. The combined pattern includes remaining portions the first set of fin structures 121 and remaining portions of the third set of fin structures 123. An example result is illustrated in FIG. 13, while FIG. 14 shows the first set of fin structures and the third set of fin structures having been removed. Accordingly fins can be patterned with desired cuts without overlay error.

In another embodiment, the first set of fin structures 121 can be cut prior to forming the third set of fin structures. FIG. 15 is identical to FIG. 1 as a starting point with the first set of fin structures 121 formed on the substrate.

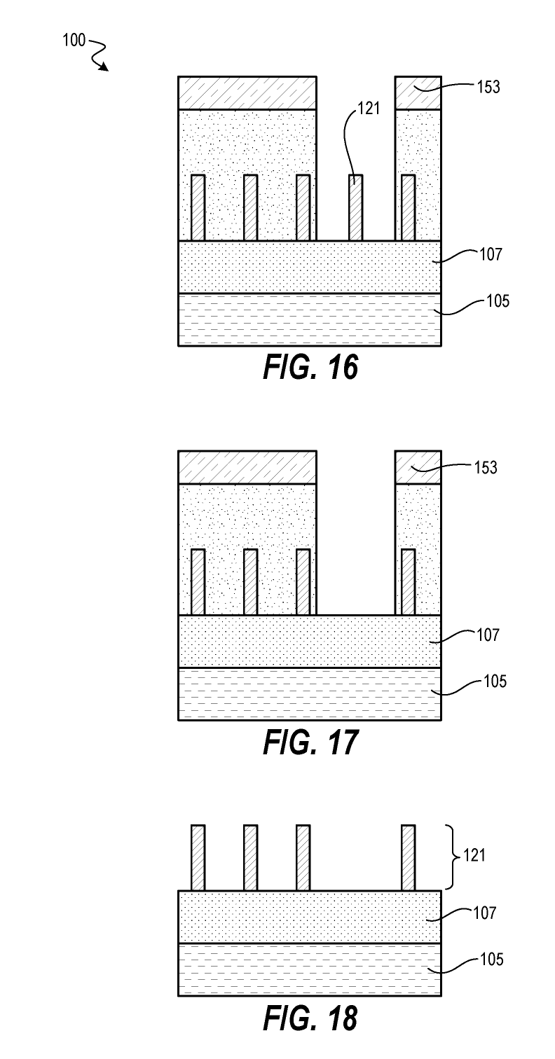

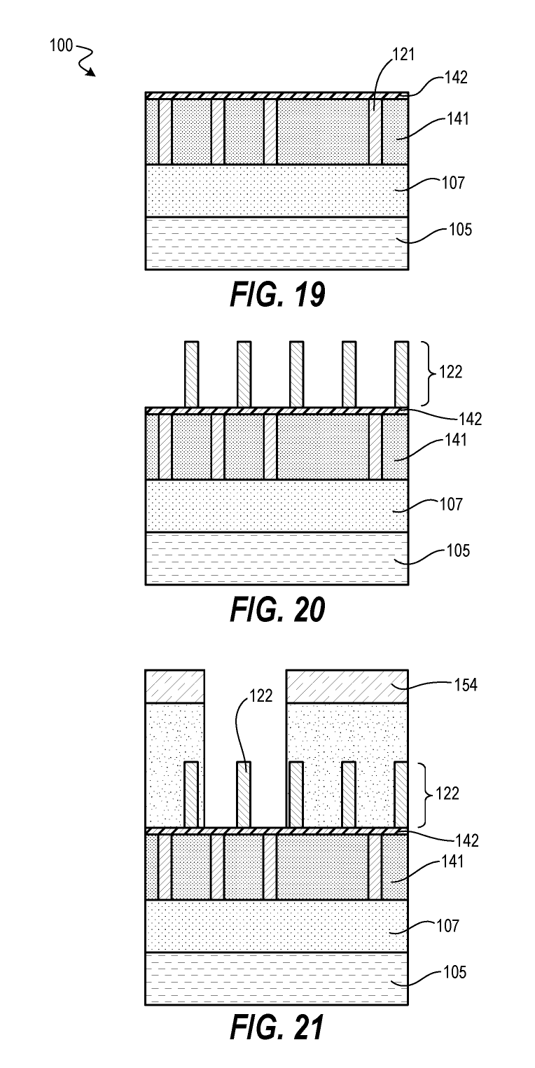

A third etch mask 153 is formed on the substrate subsequent to forming the first set of fin structures 121 and prior to planarizing the substrate (FIG. 16). Uncovered portions of the first set of fin structures are etched using the third etch mask 153 (FIG. 17) as a sixth etch process. Note that labels for etch processes are merely labels to distinguish one from another and do not necessarily indicate a processing order. The third etch mask 153 is then removed prior to planarizing the substrate (FIG. 18). The substrate is then planarized as was previously described (FIG. 19).

A second set of fin structures 122 is formed on substrate 100 (FIG. 20) similar to the formation as described for FIG. 4. The difference is that a portion of the first set of fin structures 121 has already been cut.

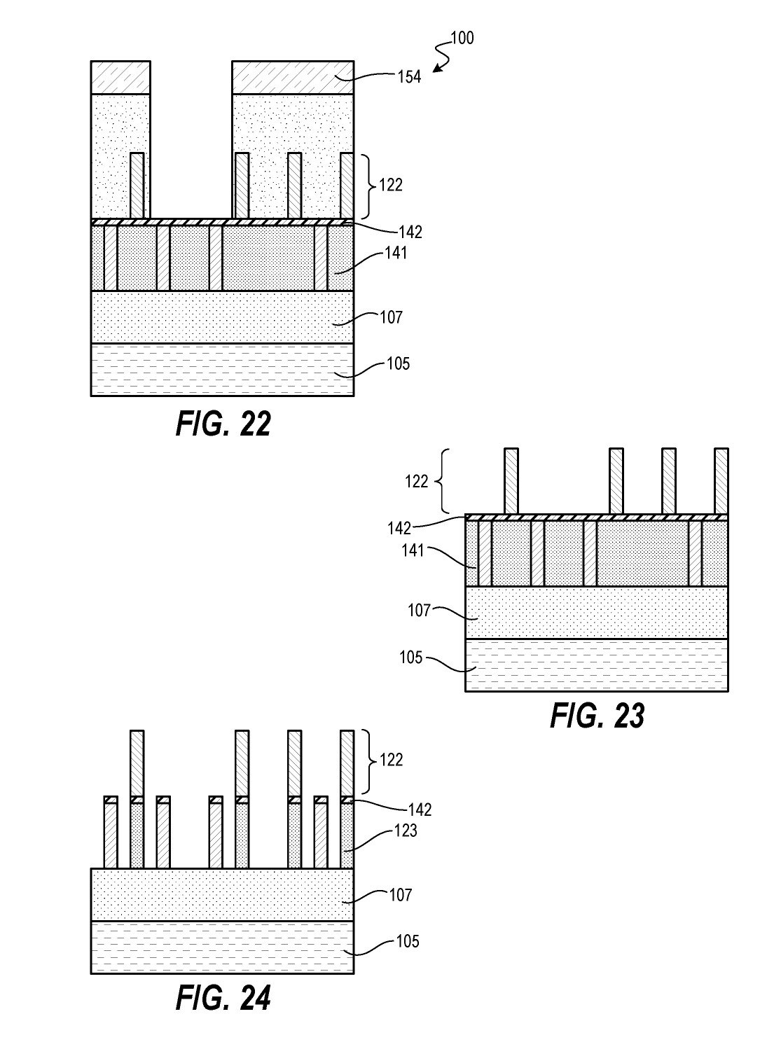

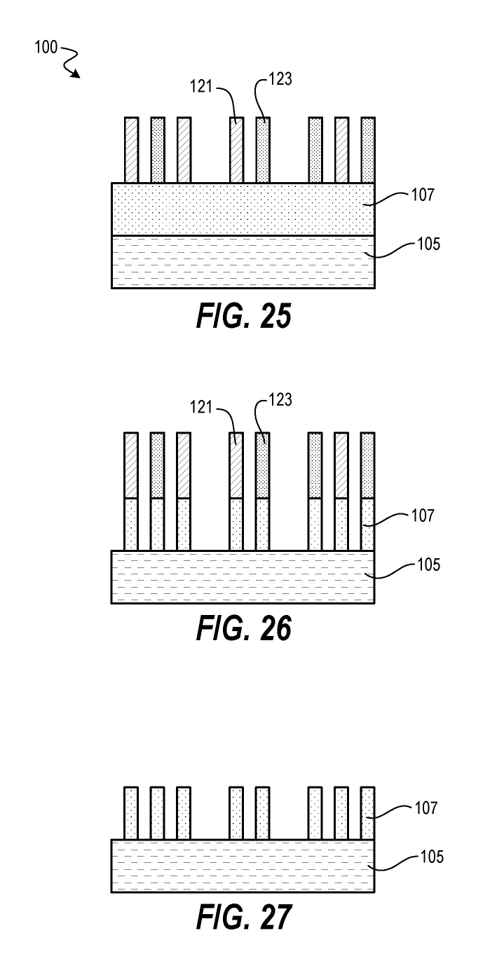

A fourth etch mask 154 is formed on the substrate subsequent to forming the second set of fin structures 122 and prior to executing the first etch process (FIG. 21). A seventh etch process is executed that etches uncovered portions of the second set of fin structures 122 using the fourth etch mask 154 (FIG. 22). The fourth etch mask 154 is removed prior to executing the first etch process (FIG. 23). The first etch process can then transfer a pattern comprising the second set of fin structures into the first fill material 141 without removing the first set of fin structures. The first etch process resulting in a third set of fin structures 123 (FIG. 24) similar to previously described. The second set of fin structures 122 can then be removed (FIG. 25). At this point the first set of fin structures 121 and the third set of fin structures 123 already have cuts and can be transferred into target layer 107 (FIG. 26). The first set of fin structures 121 and the third set of fin structures 123 can then be removed (FIG. 27). Alternatively, the sets of fin structures in FIG. 25 can be further masked and cut if desired. Also in alternative embodiments, either odd or even or both fin structure lines can be cut. Accordingly there are several different process flows using fins of alternating materials to accurately cut even with overlay error. Such configuration and techniques also enables use of slot openings for cuts, which can be easier to lithographically create in a layer of photoresist.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method of patterning a substrate, the method comprising:
forming a first set of fin structures on a substrate, the first set of fin structures formed as a first array of parallel lines, wherein a spacing of given adjacent fin structures of the first set of fin structures is sufficient to permit additional fin structures to be interposed among fin structures of the first set of fin structures to result in an array of alternating fin structures with space between a given fin structure of the first set of fin structures and a given adjacent fin structure of additional fin structures;
planarizing the substrate by depositing a first fill material that fills spaces between fin structures of the first set of fin structures;
forming a second set of fin structures on the substrate, the second set of fin structures formed as a second array of parallel lines, wherein the second set of fin structures is positioned so that fin structures of the second set of fin structures are elevationally interposed with fin structures of the first set of fin structures; and
executing a first etch process that transfers a pattern comprising the second set of fin structures into the first fill material without removing the first set of fin structures, the first etch process resulting in a third set of fin structures, wherein fin structures of the third set of fin structures alternate with fin structures of the first set of fin structures, the third set of fin structures being in plane with the first set of fin structures, wherein the first set of fin structures have a different etch resistivity as compared to the third set of fin structures.

2. The method of claim 1, further comprising:
forming a first etch mask on the substrate that uncovers portions of the first set of fin structures and portions of the third set of fin structures; and
executing a second etch process using the first etch mask, the second etch process etching uncovered portions of the first set of fin structures at a greater rate than etching of uncovered portions of the third set of fin structures until uncovered portions of the first set of fin structures are removed from the substrate while uncovered portions of the third set of fin structures remain on the substrate.

3. The method of claim 2, further comprising:
executing a third etch process using the first etch mask, the third etch process etching uncovered portions of the third set of fin structures until uncovered portions of the third set of fin structures are removed from the substrate.

4. The method of claim 3, further comprising:
executing a fifth etch process that transfers a combined pattern into an underlying layer, the combined pattern including remaining portions the first set of fin structures and remaining portions of the third set of fin structures.

5. The method of claim 2, further comprising:
forming a second etch mask on the substrate that uncovers portions of the first set of fin structures and portions of the third set of fin structures; and
executing a fourth etch process using the second etch mask, the fourth etch process etching uncovered portions of the third set of fin structures at a greater rate than etching of uncovered portions of the first set of fin structures until uncovered portions of the third set of fin structures are removed from the substrate while uncovered portions of the first set of fin structures remain on the substrate.

6. The method of claim 5, further comprising:
executing a fifth etch process that transfers a combined pattern into an underlying layer, the combined pattern including remaining portions the first set of fin structures and remaining portions of the third set of fin structures.

7. The method of claim 1, wherein the first set of fin structures is formed as sidewall spacers, and wherein the second set of fin structures is formed as sidewall spacers.

8. The method of claim 1, wherein a pitch of the first set of fin structures is at least twice a design pitch of fins in a given region of the substrate.

9. The method of claim 1, further comprising:
forming a third etch mask on the substrate subsequent to forming the first set of fin structures and prior to planarizing the substrate;
executing a sixth etch process that etches uncovered portions of the first set of fin structures using the third etch mask; and
removing the third etch mask prior to planarizing the substrate.

10. The method of claim 9, further comprising:
forming a fourth etch mask on the substrate subsequent to forming the second set of fin structures and prior to executing the first etch process;
executing a seventh etch process that etches uncovered portions of the second set of fin structures using the fourth etch mask; and
removing the fourth etch mask prior to executing the first etch process.

11. The method of claim 1, further comprising:
forming a fourth etch mask on the substrate subsequent to forming the second set of fin structures and prior to executing the first etch process;
executing a seventh etch process that etches uncovered portions of the second set of fin structures using the fourth etch mask; and
removing the fourth etch mask prior to executing the first etch process.

12. The method of claim 11, further comprising:
forming a first etch mask on the substrate that uncovers portions of the first set of fin structures and portions of the third set of fin structures; and
executing a second etch process using the first etch mask, the second etch process etching uncovered portions of the first set of fin structures at a greater rate than etching of uncovered portions of the third set of fin structures until uncovered portions of the first set of fin structures are removed from the substrate while uncovered portions of the third set of fin structures remain on the substrate.
